(19) United States
(12) Patent Application Publication
(10) Pub. No.: US 2011/0024179 A1
(43) Pub. Date: Feb. 3, 2011

(54) METHOD FOR PRODUCING CIRCUIT BOARD AND CIRCUIT BOARD

(75) Inventor: Akihiro Nomoto, Kanagawa (JP)

Correspondence Address: K&L Gates LLP, P. O. BOX 1135, CHICAGO, IL, 60690, US

(73) Assignee: SONY CORPORATION, Tokyo (JP)

(21) Appl. No.: 12/836,058

(22) Filed: Jul. 14, 2010

(30) Foreign Application Priority Data
Jul. 30, 2009 (JP) P2009-177561

(51) Int. Cl. H05K 1/11; H01L 21/329

(52) U.S. Cl. 174/262; 438/572; 257/E21.359

(57) ABSTRACT

A method for producing a circuit board, the method includes the steps of: forming a lower wiring pattern on a substrate; forming an insulating film on the substrate to cover the lower wiring pattern; forming an opening in the insulating film to expose the lower wiring pattern; forming an upper wiring pattern on the insulating film; and forming an interconnect material pattern on a sidewall of the opening in the insulating film for connecting the lower wiring pattern and the upper wiring pattern.

### CROSS REFERENCES TO RELATED APPLICATIONS

The present application claims priority to Japanese Priority Patent Application JP 2009-177561 filed in the Japan Patent Office on Jul. 30, 2009, the entire contents of which is hereby incorporated by reference.

### BACKGROUND

The present application relates to a method for producing a circuit board and also to a circuit board. It particularly relates to a method for producing a circuit board having a stacked interconnect structure and also to a circuit board having a stacked interconnect structure.

In recent years, devices using organic semiconductor materials have been actively developed. An organic semiconductor material can be formed into a film by a printing method or by a coating method without the need for a vacuum process or a thermal process. Such an organic semiconductor material thus achieves low cost and also allows the use of a plastic material for a substrate.

A device using an organic semiconductor material, for example, a thin film transistor, is produced by a method in which a wiring pattern including a source electrode and a drain electrode is formed, and then an organic semiconductor layer is formed thereon by printing using a stamp, for example (see, e.g., JP-A-2007-67390). Another method has also been proposed, in which a barrier layer made of an insulating material is formed on a substrate having formed thereon a wiring pattern including a source electrode and a drain electrode, and then an organic semiconductor material solution is installed to an opening in the barrier layer, followed by drying, thereby forming an organic semiconductor layer between the source electrode and the drain electrode (see, e.g., JP-A-2008-227141).

Incidentally, in a circuit board having wiring patterns together with a device made of an organic semiconductor material, a stacked interconnect structure is employed to achieve high integration. The production of such a circuit board having a stacked structure includes the steps of first forming a lower wiring pattern and a device on a substrate, then forming an insulating film to cover them, and forming an upper wiring pattern connected to the lower wiring pattern or the device through a connection hole formed in the insulating film.

In particular, regarding the form of connection between the upper and lower wiring patterns, a method has also been proposed, in which a via is formed in a lower wiring pattern by printing, and then an insulating film is formed to fill in the via. Subsequently, the insulating film is removed from the via, and then an upper wiring pattern connected to the via is formed on the insulating film (see JP-A-2008-311630 (in particular, FIGS. 13 to 15 and related descriptions)).

### SUMMARY

However, in the above-mentioned methods for producing a circuit board, the formation process of the upper wiring pattern affects the already formed lower wiring pattern or device made of an organic semiconductor material. For example, in the case where the upper wiring pattern is formed by a printing method, in the baking process, degradation occurs in the organic semiconductor layer forming the device, etc., and this results in degradation of device characteristics.

Thus, it is desirable to provide a method for producing a circuit board having a stacked interconnect structure, capable of preventing degradation of circuit characteristics, and also provide a circuit board having excellent circuit characteristics by such a method.

According to an embodiment, there is provided a method for producing a circuit board, including the following steps. First, a lower wiring pattern is formed on a substrate, and an insulating film is formed thereon to cover the lower wiring pattern. Then, an opening is formed in the insulating film to expose the lower wiring pattern. Further, an upper wiring pattern is formed on the insulating film. Subsequently, an interconnect material pattern for connecting the lower wiring pattern and the upper wiring pattern is formed on the sidewall of the opening in the insulating film.

In such a method for producing a circuit board, because the interconnect material pattern is formed after the upper wiring pattern is formed, the formation of the upper wiring pattern does not affect the interconnect material pattern. Therefore, even in the case where the interconnect material pattern is made of an organic semiconductor material or the like, the film quality of the interconnect material pattern can be maintained. As a result, the characteristics of a device using the interconnect material pattern can be maintained.

According to another embodiment, there is provided a circuit board produced as above. The circuit board has a lower wiring pattern formed on a substrate, an insulating film having an opening to expose a part of the lower wiring pattern and covering the substrate having formed thereon the lower wiring pattern, and an upper wiring pattern formed on the insulating film. In particular, the interconnect material pattern is provided from the sidewall of the upper wiring pattern through the sidewall of the opening to the top surface of the lower wiring pattern exposed at the bottom of the opening.

According to the above embodiments, in a configuration with a stacked interconnect structure, degradation of circuit characteristics is prevented, making it possible to provide a circuit board having excellent characteristics.

Additional features and advantages are described herein, and will be apparent from the following Detailed Description and the figures.

### BRIEF DESCRIPTION OF THE FIGURES

FIGS. 1A to 1D show a flow chart illustrating a method according to a first embodiment in cross section.

FIGS. 2A to 2D show a flow chart (I) illustrating a method according to a second embodiment in cross section.

FIGS. 3A and 3B show a flow chart (II) illustrating the method according to the second embodiment in cross section.

FIG. 4 is a schematic diagram showing a variation of the second embodiment.

### DETAILED DESCRIPTION

The present application is described below in detail with reference to the drawings according to an embodiment. The detailed description is provided as follows:

1. First Embodiment (production example of circuit board having Schottky diode)

2. Second Embodiment (production example of circuit board integrating multiple devices)

3. Variation of Second Embodiment (formation of coil)

### First Embodiment

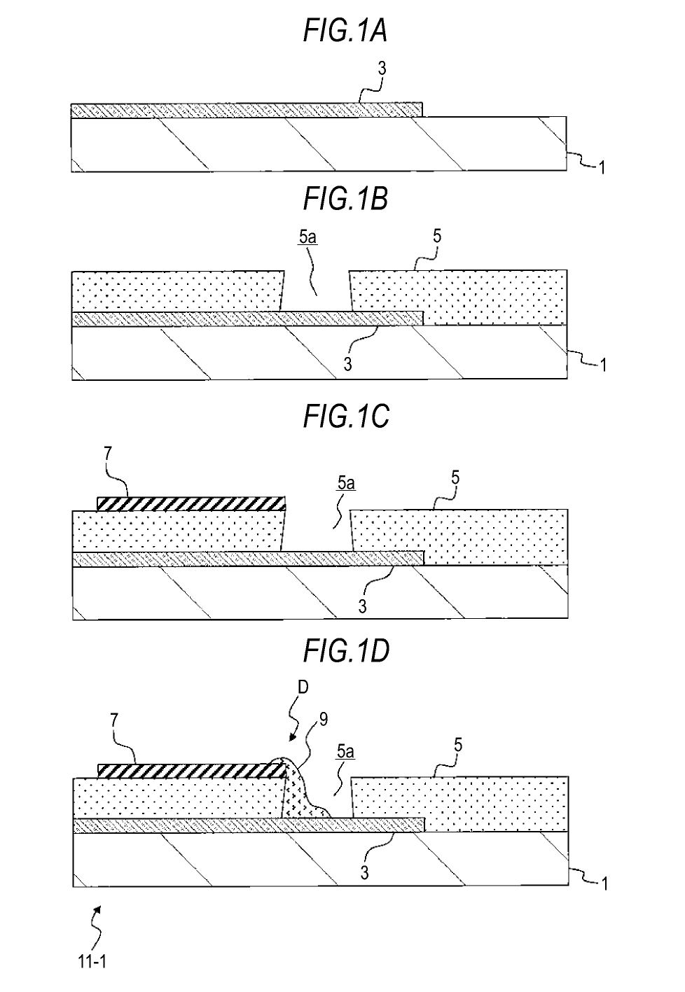

FIGS. 1A to 1D show a flow chart illustrating a method according to a first embodiment in cross section. With reference to the figures, the following will describe the first embodiment as applied to the production of a circuit board having a Schottky diode.

First, as shown in FIG. 1A, a lower wiring pattern 3 is formed on a substrate 1. The substrate 1 has insulating properties at least in the surface thereof. The substrate 1 may be a plastic substrate made of PES (polyethersulfone), PEN (polyethylene naphthalate), PET (polyethylene terephthalate), PC (polycarbonate), or the like, for example. The substrate 1 may alternatively be a substrate formed by laminating a stainless-steel (SUS) metal foil or the like with resin, a glass substrate, or the like. In order to achieve flexibility, a plastic substrate or a metal foil substrate is employed.

The lower wiring pattern 3 is formed using a material that forms an ohmic junction with an interconnect material pattern to be formed in a later step using an organic semiconductor material. The junction to the interconnect material pattern is controlled by the work function of the surface of the lower wiring pattern 3.

Such a lower wiring pattern 3 is formed as follows, for example: a metal material film is formed by a coating method using an organic silver (Ag) ink, then a resist pattern is formed thereon by lithography, and the metal material film is pattern-etched using the resist pattern as a mask. The lower wiring pattern 3 may also be formed by a printing method such as screen printing, gravure printing, flexographic printing, offset printing, or inkjet printing.

Subsequently, as shown in FIG. 1B, an insulating film 5 is formed on the substrate 1 to cover the lower wiring pattern 3. In this step, the insulating film 5 is formed by a coating method using, for example, a photosensitive composition. An opening 5a is then formed in the insulating film 5 by lithography to expose the lower wiring pattern 3. In this step, by suitably selecting the resist material, for example, the opening 5a is formed to have a reverse-tapered sidewall such that the width of the opening decreases towards the top of the opening.

The formation of the opening 5a in the insulating film 5 may be performed, after the insulating film 5 is formed using a suitable insulating material, by forming a resist pattern thereon, and pattern-etching the insulating film 5 using the resist pattern as a mask. The opening 5a may also be formed by applying a laser beam to the insulating film 5 formed using a suitable insulating material. It is also possible to employ a printing method to form the insulating film 5 provided with the opening 5a beforehand.

Subsequently, as shown in FIG. 1C, an upper wiring pattern 7 is formed on the insulating film 5. The upper wiring pattern 7 is formed using a material that forms a Schottky junction with an interconnect material pattern formed in the following step using an organic semiconductor material. The junction to the interconnect material pattern is controlled by the work function of the surface of the upper wiring pattern 7.

Such an upper wiring pattern 7 is formed by a printing method using an organic protective film silver (Ag) nanocolloid ink, for example. In this case, it is particularly preferable to employ dry stamping. Use of dry stamping makes it possible to form the upper wiring pattern 7 only on the top surface of the insulating film 5, without forming the upper wiring pattern 7 on the sidewall of the opening 5a. In particular, when the opening 5a has a reverse-tapered sidewall as mentioned above, the upper wiring pattern 7 can be cut off more easily at the edge of the opening 5a, and the upper wiring pattern 7 is less likely to form on the sidewall of the opening 5a.

Even in the case where the opening 5a does not have a reverse-tapered sidewall, by controlling the printing conditions and the conditions such as the aspect ratio of the opening 5a, the upper wiring pattern 7 can be cut off at the edge of the opening 5a, avoiding the formation of the upper wiring pattern 7 on the lower wiring pattern 3. The upper wiring pattern 7 may be provided also on the sidewall of the opening 5a unless it is directly connected to the lower wiring pattern 3.

After forming the upper wiring pattern 7 by such a printing method, sintering is performed to remove the organic protective film from the organic protective film silver (Ag) nanocolloid ink. At this time, some of the organic protective film remains, thereby controlling the electrical characteristics of the surface of the upper wiring pattern 7. For example, in the case of PVP protective film Ag nanoparticles, the work function thereof increases after sintering as compared with the case of Ag metal. Further, the work functions of Ag materials can be independently controlled depending on the kind of the protective film.

In addition to the control by the organic protective film forming an ink as above, the electrical characteristics (work function) of the surface of the upper wiring pattern 7 may also be controlled by the selection of the material based on the work function or by the application of surface treatment to the upper wiring pattern 7.

Subsequently, as shown in FIG. 1D, an interconnect material pattern 9 is formed by a printing method on the sidewall of the opening 5a in the insulating film 5 having formed thereon the upper wiring pattern 7. The interconnect material pattern 9 connects the lower wiring pattern 3 and the upper wiring pattern 7. In this step, in particular, the interconnect material pattern 9 is formed using an organic semiconductor material. It is preferable that the interconnect material pattern 9 is provided from the top surface of the lower wiring pattern 3 exposed at the bottom of the opening 5a through the sidewall of the opening 5a to the sidewall of the upper wiring pattern 7 or further to the top surface of the upper wiring pattern 7. Therefore, the interconnect material pattern 9 may be provided to fill in the opening 5a unless it affects the other upper wiring pattern 7 on the insulating film 5. It is also possible that the interconnect material pattern 9 that is sufficiently thinner than the insulating film 5 is provided along the inner wall of the opening 5a to cover the inner wall.

The interconnect material pattern 9 is printed and formed by inkjet printing, for example. In this case, using TIPS pentacene (6,13-bis(triisopropylsilylethynyl)pentacene) as an organic semiconductor material, an ink is prepared as a mixture with a polymeric material (e.g., PaMS: Poly-α-methylstyrene), and the prepared ink is used in inkjet printing. After printing, drying is performed to give the interconnect material pattern 9.

In the case where the interconnect material pattern 9 is formed by a printing method other than inkjet printing, it is preferable that the opening 5a has a forward-tapered sidewall such that the width of the opening increases towards the top of the opening. This facilitates the printing formation of the interconnect material pattern 9 on the forward-tapered sidewall. However, in the case of inkjet printing, the opening 5a may have a reverse-tapered sidewall, as inkjet printing allows the ink to be supplied to the bottom corners of the opening 5a.

Thus, on the substrate 1, the interconnect material pattern 9 made of an organic semiconductor material forms an ohmic junction with the lower wiring pattern 3 and a Schottky junction with the upper wiring pattern 7, thereby forming a Schottky diode D. After these steps, although not illustrated in the figures, an insulating, protective film is formed above the substrate 1. A circuit board 11-1 is thus completed.

The thus-obtained circuit board 11-1 is configured to include the lower wiring pattern 3, the insulating film 5, and the upper wiring pattern 7 stacked in this order, in which the upper wiring pattern 7 and the lower wiring pattern 3 are connected by the interconnect material pattern 9 provided on the sidewall of the opening 5a in the insulating film 5. In particular, the interconnect material pattern 9 is formed after the formation of the upper wiring pattern 7. Thus, the interconnect material pattern 9 is provided at least from the sidewall of the upper wiring pattern 7 through the sidewall of the opening 5a to the top surface of the lower wiring pattern 3 exposed at the bottom of the opening 5a. In order to ensure the connection between the upper wiring pattern 7 and the interconnect material pattern 9, the interconnect material pattern 9 may be also provided on the top surface of the upper wiring pattern 7.

In addition, in the circuit board 11-1, the interconnect material pattern 9 is made of an organic semiconductor material, and forms a Schottky junction with the upper wiring pattern 7 to form the Schottky diode D. The Schottky diode is a vertical diode utilizing the sidewall of the opening 5a.

According to such a first embodiment, the interconnect material pattern 9 is formed after the upper wiring pattern 7 is formed. Therefore, the formation process of the upper wiring pattern 7 does not affect the interconnect material pattern 9. Accordingly, during the formation of the upper wiring pattern 7, although the printed organic protective film silver (Ag) nanocolloid ink is sintered, this thermal process does not cause degradation of the interconnect material pattern 9 made of an organic semiconductor material. The Schottky diode D formed using the interconnect material pattern 9 thus has excellent diode characteristics, and the circuit board 11-1 including the Schottky diode can be provided with improved circuit characteristics.

The Schottky diode D is a vertical diode utilizing the sidewall of the opening 5a. Accordingly, the area occupied by the diode D is reduced, and this achieves even higher integration on the circuit board 11-1.

In addition, although the interconnect material pattern 9 forms a Schottky junction with the upper wiring pattern 7 and an ohmic junction with the lower wiring pattern 3 in the above-described first embodiment, the junctions may alternatively be reversed in the first embodiment. However, for eliminating the effects on the already formed lower wiring pattern 3, it is preferable to form the upper wiring pattern 7 using a material capable of forming the pattern in a less stressful process.

Further, in the above-described first embodiment, the interconnect material pattern 9 formed using an organic semiconductor material may alternatively be one made of an electrically conductive material, and such an interconnect material pattern 9 between the lower wiring pattern 3 and the upper wiring pattern 7 may be used as a connecting plug. In such a case, the interconnect material pattern 9 may be formed by a printing method using a silver (Ag) paste, for example. In this case, it is preferable that the sidewall of the opening 5a of the insulating film 5 is forward-tapered. When the upper wiring pattern 7 is formed, the upper wiring pattern 7 may be connected to the lower wiring pattern 3. The interconnect material pattern 9 made of a silver (Ag) paste and the upper wiring pattern 7 may be sintered in the same step, and, therefore, the process can be simplified.

Even in the case where the interconnect material pattern 9 is formed using an organic semiconductor material, when the lower wiring pattern 3 and the upper wiring pattern 7 are formed from the same material, the interconnect material pattern 9 portion can be used as a resistor.

### Second Embodiment

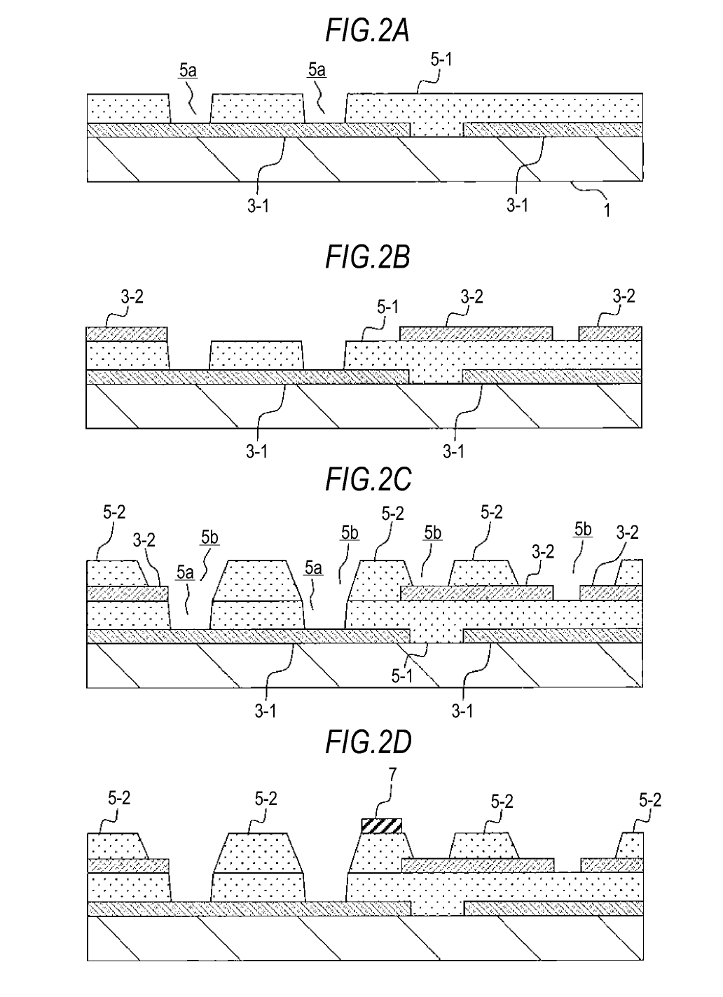

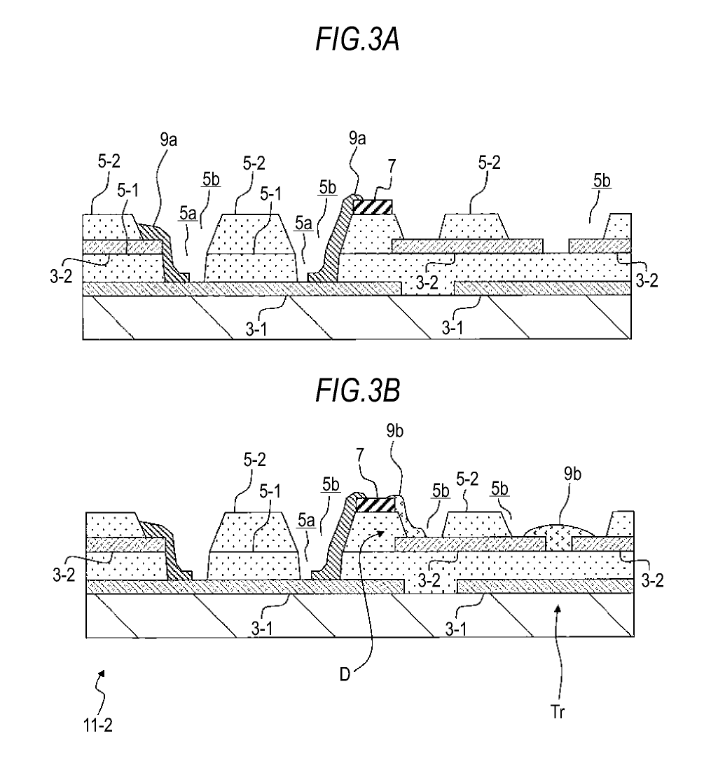

FIGS. 2A to 2D and FIGS. 3A and 3B show flow charts illustrating a method according to a second embodiment in cross section. With reference to the figures, the following will describe a second embodiment as applied to the production of an integrated circuit board. The components common to the first embodiment are indicated with the same reference numerals, and will not be further described.

First, as shown in FIG. 2A, a first lower wiring pattern 3-1 is formed on a substrate 1. Further, a first insulating film 5-1 is formed thereon, and an opening 5a is formed therein. These steps are performed in the same manner as described in the first embodiment with reference to FIG. 1A and FIG. 1B. The first lower wiring pattern 3-1 is equivalent to the lower wiring pattern 3 in the first embodiment, and the first insulating film 5-1 is equivalent to the insulating film 5 in the first embodiment. However, the materials for the first lower wiring pattern 3-1 are not limited. In addition, it is preferable that the opening 5a in the first insulating film 5-1 has a forward-tapered sidewall.

Subsequently, as shown in FIG. 2B, a second lower wiring pattern 3-2 is formed on the first insulating film 5-1. The second lower wiring pattern 3-2 is formed using a material that forms an ohmic junction with an interconnect material pattern to be formed in a later step using an organic semiconductor material. The junction to the interconnect material pattern is controlled by the work function of the surface of the second lower wiring pattern 3-2.

Such a second lower wiring pattern 3-2 is formed by a printing method using an organic silver (Ag) ink, for example. In this case, it is particularly preferable to employ dry stamping. Use of dry stamping makes it possible to form the second lower wiring pattern 3-2 only on the top surface of the first insulating film 5-1, without forming the second lower wiring pattern 3-2 on the sidewall of the opening 5a. At this time, by controlling the printing conditions and the conditions such as the aspect ratio of the opening 5a, the second lower wiring pattern 3-2 can be cut off at the edge of the opening 5a, avoiding the formation of the second lower wiring pattern 3-2 on the first lower wiring pattern 3-1. The second lower wiring pattern 3-2 may be provided also on the sidewall of the opening 5a unless it is directly connected to the first lower wiring pattern 3-1.

Subsequently, as shown in FIG. 2C, a second insulating film 5-2 is formed on the first insulating film 5-1 to cover the second lower wiring pattern 3-2, and an opening 5b is formed in the second insulating film 5-2. The second insulating film 5-2 and the opening 5b are formed in the same manner as in the formation of the insulating film 5 and the opening 5a described in the first embodiment with reference to FIG. 1B.

In this step, some openings 5b are located directly above the openings 5a in the first insulating film 5-1 to expose the first lower wiring pattern 3-1 at the bottom, while other openings 5b are located to expose the second lower wiring pattern 3-2 at the bottom. Here, as an example, two openings 5b are formed to expose the first lower wiring pattern 3-1, and two openings 5b are formed to expose the second lower wiring pattern 3-2.

One of the openings 5b for exposing the second lower wiring pattern 3-2 is formed to expose only the second lower wiring pattern 3-2 at the bottom, and the other is formed to expose two parts of the second lower wiring pattern 3-2 at the bottom. The opening 5a in the first insulating film 5-1 in this case has a forward-tapered sidewall.

Subsequently, as shown in FIG. 2D, an upper wiring pattern 7 is formed on the second insulating film 5-2. The upper pattern 7 is formed in the same manner as in the formation of the upper pattern 7 described in the first embodiment with reference to FIG. 1C.

That is, the upper wiring pattern 7 is formed using a material that forms a Schottky junction with the interconnect material pattern formed in the following step using an organic semiconductor material, and a printing method is employed for the formation. A preferred example of the printing method is dry stamping using an organic protective film silver (Ag) nanocolloid ink. Use of dry stamping makes it possible to form the upper wiring pattern 7 only on the top surface of the second insulating film 5-2, without forming the upper wiring pattern 7 on the sidewall of the opening 5b. At this time, by controlling the printing conditions and conditions such as the aspect ratio of the opening 5b, the upper wiring pattern 7 can be cut off at the edge of the opening 5b, avoiding the formation of the upper wiring pattern 7 on the second lower wiring pattern 3-2. The upper wiring pattern 7 may also be formed on the sidewalls of the openings 5a and 5b unless it is directly connected to the lower wiring patterns 3-1 and 3-2.

After forming the upper wiring pattern 7 by a printing method, sintering is performed to remove the organic protective film from the organic protective film silver (Ag) nanocolloid ink. At this time, some of the organic protective film remains, thereby controlling the electrical characteristics of the surface of the upper wiring pattern 7. As a result, in the case of a PVP protective film, the work function increases.

Subsequently, as shown in FIG. 3A, a first interconnect material pattern 9a made of an electrically conductive material is formed on the sidewalls of the openings 5a and 5b in the insulating films 5-1 and 5-2 provided with the upper wiring pattern 7. The first interconnect material pattern 9a is positioned to connect the first lower wiring pattern 3-1 and the upper wiring pattern 7 and is also positioned to connect the first lower wiring pattern 3-1 and the second lower wiring pattern 3-2. Such a first interconnect material pattern 9a is formed by screen printing using a silver (Ag) paste, for example.

It is preferable that the first interconnect material pattern 9a is provided from the top surface of the first lower wiring pattern 3-1 exposed at the bottom of the openings 5a and 5b through the sidewall of the opening 5a, the sidewall of the second lower wiring pattern 3-2, the sidewall of the opening 5b, then to the sidewall of the upper wiring pattern 7 or further to the top surface of the upper wiring pattern 7. Therefore, the first interconnect material pattern 9a may be provided to fill in the openings 5a and 5b unless it affects the other upper wiring pattern 7 on the second insulating film 5-2. It is also possible that the first interconnect material pattern 9a that is sufficiently thinner than the insulating films 5-1 and 5-2 is provided along the inner wall of the opening 5a to cover the inner wall.

After the first interconnect material pattern 9a made of an electrically conductive material is formed as above, sintering is performed. The upper wiring pattern 7 may be sintered in the same step as the sintering of the first interconnect material pattern 9a, and, therefore, the process can be simplified.

Subsequently, as shown in FIG. 3B, a second interconnect material pattern 9b made of an organic semiconductor material is formed on the sidewall and bottom of the opening 5b in the second insulating film 5-2 provided with the upper wiring pattern 7. The second interconnect material pattern 9b is formed in the same manner as in the formation of the interconnect material pattern 9 described in the first embodiment with reference to FIG. 1D.

That is, the second interconnect material pattern 9b is formed by inkjet printing, for example. It is preferable that the second interconnect material pattern 9b is provided from the top surface of the second lower wiring pattern 3-2 exposed at the bottom of the opening 5b through the sidewall of the opening 5b to the sidewall of the upper wiring pattern 7 or further to the top surface of the upper wiring pattern 7. Therefore, the second interconnect material pattern 9b may be provided to fill in the opening 5b unless it affects the other upper wiring pattern 7 on the second insulating film 5-2. It is also possible that the second interconnect material pattern 9b that is sufficiently thinner than the second insulating film 5-2 is provided along the inner wall of the opening 5b to cover the inner wall.

Thus, in the position where the interconnect material pattern 9b made of an organic semiconductor material is formed between the second lower wiring pattern 3-2 and the upper wiring pattern 7, the interconnect material pattern 9b forms a Schottky junction with the upper wiring pattern 7, thereby forming a Schottky diode D. Meanwhile, in the position where the interconnect material pattern 9b made of an organic semiconductor material is formed between the two parts of the second lower wiring pattern 3-2, the interconnect material pattern 9b forms an ohmic junction with the second lower wiring pattern 3-2, thereby forming a thin film transistor Tr. The thin film transistor Tr uses the first lower wiring pattern 3-1 as its gate electrode.

After these steps, although not illustrated in the figures, an insulating, protective film is formed above the substrate 1. A circuit board 11-2 is thus completed.

The thus-obtained circuit board 11-2 is configured such that the upper wiring pattern 7 is connected to the lower wiring patterns 3-1 and 3-2 by the interconnect material patterns 9a and 9ab provided on the sidewalls of the openings 5a and 5b formed in the insulating films 5-1 and 5-2, respectively. In particular, the interconnect material patterns 9a and 9b are formed after the formation of the upper wiring pattern 7. Thus, the interconnect material patterns 9a and 9b are provided at least from the sidewall of the upper wiring pattern 7 to the top surface of the lower wiring pattern 3-1 through the sidewalls of the opening 5a and 5b, respectively. In order to ensure the connection between the upper wiring pattern 7 and the interconnect material patterns 9a and 9b, the interconnect material patterns 9a and 9b may also be provided on the top surface of the upper wiring pattern 7.

Further, in the circuit board 11-2, the second interconnect material pattern 9b is made of an organic semiconductor material, and forms the Schottky diode D and the thin film transistor Tr. In particular, the Schottky diode D is a vertical diode utilizing the sidewall of the opening 5b.

According to the second embodiment, the second interconnect material pattern 9b is formed after the upper wiring pattern 7 is formed. Therefore, the formation process of the upper wiring pattern 7 does not affect the second interconnect material pattern 9b. Accordingly, during the formation of the upper wiring pattern 7, although the printed organic protective film silver (Ag) nanocolloid ink is sintered, this thermal process does not cause degradation of the second interconnect material pattern 9b made of an organic semiconductor material. The Schottky diode D formed using the second interconnect material pattern 9b thus has excellent diode characteristics, and the circuit board 11-2 including the Schottky diode D can be provided with improved circuit characteristics.

The Schottky diode D is a vertical diode utilizing the sidewall of the opening 5b. Accordingly, the area occupied by the diode D is reduced, and this achieves even higher integration on the circuit board 11-2.

In the above-described second embodiment, the second interconnect material pattern 9b made of an organic semiconductor material is provided between the upper wiring pattern 7 and the second lower wiring pattern 3-2 to form the Schottky diode D. However, in the second embodiment, the second interconnect material pattern 9b may be provided between the upper wiring pattern 7 and the first lower wiring pattern 3-1 to form the Schottky diode D. Likewise, the second interconnect material pattern 9b may also be formed between parts of the first lower wiring pattern 3-1 to form the thin film transistor Tr. Also in these cases, when the second interconnect material pattern 9b is formed after the formation of the upper wiring pattern 7, the same effects can be achieved.

The interconnect wiring patterns 9a and 9b may also be provided to connect the first lower wiring pattern 3-1, the second lower wiring pattern 3-2, and the upper wiring pattern 7. Also in such a case, insofar as the second interconnect material pattern 9b made of an organic semiconductor material is formed after the formation of the upper wiring pattern 7, the same effects can be achieved.

### Variation of Second Embodiment

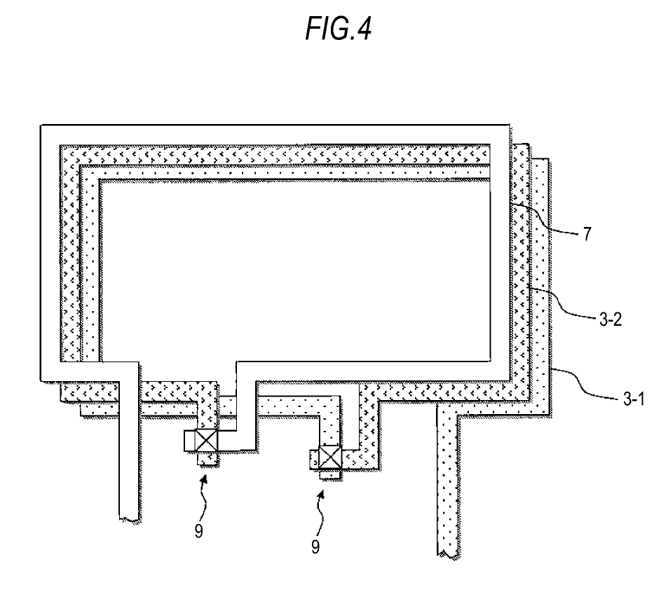

FIG. 4 is a schematic diagram showing the configuration of a circuit board provided with a coil as an example of application of the second embodiment.

As shown in the figure, the coil of the application example of the second embodiment includes a plurality of coil-shaped lower wiring patterns 3-1 and 3-2 that are stacked with non-illustrated insulating films in between. On the topmost insulating film, a coil-shaped upper wiring pattern 7 is stacked. An opening is formed in one of the insulating films to expose, among the lower wiring patterns 3-1 and 3-2 and the upper wiring pattern 7, only two wiring patterns that are closest to each other. An interconnect material pattern 9 made of an electrically conductive material is formed in such an opening to connect the two wiring patterns. Such a coil can be used as a loop antenna.

In the case where the interconnect material pattern 9 is made of an organic semiconductor material, a Schottky diode D or a resistor can be formed in that area. Therefore, it is also possible to form a circuit including a combination of a coil with a Schottky diode or a resistor. In this case, what is necessary is to form only the interconnect material pattern made of an organic semiconductor material after the formation of the upper wiring pattern 7; as a result, the same effects as in the second embodiment can be achieved.

It should be understood that various changes and modifications to the presently preferred embodiments described herein will be apparent to those skilled in the art. Such changes and modifications can be made without departing from the spirit and scope and without diminishing its intended advantages. It is therefore intended that such changes and modifications be covered by the appended claims.

The application is claimed as follows:

1. A method for producing a circuit board, the method comprising:
forming a lower wiring pattern on a substrate;
forming an insulating film on the substrate to cover the lower wiring pattern;
forming an opening in the insulating film to expose the lower wiring pattern;
forming an upper wiring pattern on the insulating film; and
forming an interconnect material pattern on a sidewall of the opening in the insulating film for connecting the lower wiring pattern and the upper wiring pattern.

2. A method for producing a circuit board according to claim 1, wherein the interconnect material pattern is formed using an organic semiconductor material.

3. A method for producing a circuit board according to claim 2, wherein the interconnect material pattern forms a Schottky junction with one of the lower wiring pattern and the upper wiring pattern and an Ohmic junction with the other of the lower wiring pattern and the upper wiring pattern, thereby forming a Schottky diode.

4. A method for producing a circuit board according to any one of claim 1, wherein the interconnect material pattern is formed by inkjet printing.

5. A method for producing a circuit board according to claim 1, wherein the upper wiring pattern is formed by dry stamping on the insulating film having formed therein the opening.

6. A method for producing a circuit board according to claim 5, wherein the opening has a reverse-tapered sidewall such that the width of the opening decreases towards the top of the opening.

7. A method for producing a circuit board according to claim 1, wherein the opening is formed in the insulating film by lithography.

8. A circuit board comprising:
a lower wiring pattern formed on a substrate;
an insulating film having an opening to expose a part of the lower wiring pattern and covering the substrate having formed thereon the lower wiring pattern;
an upper wiring pattern formed on the insulating film; and
an interconnect material pattern provided from a sidewall of the upper wiring pattern through a sidewall of the opening to a top surface of the lower wiring pattern exposed at the bottom of the opening.

9. A circuit board according to claim 8, wherein the interconnect material pattern is formed using an organic semiconductor material.
